(19) United States
(12) Patent Application Publication
(10) Pub. No.: US 2023/0393211 A1
(43) Pub. Date: Dec. 7, 2023

(54) A METHOD FOR MONITORING AND CONTROLLING AT LEAST ONE RECHARGEABLE BATTERY, A RECHARGEABLE BATTERY, A RECHARGEABLE POWER SUPPLY SYSTEM

(71) Applicant: LITIOHM SPA, Antofagasta (CL)

(72) Inventor: Renato Humberto VARGAS DIAZ, Santiago (CL)

(21) Appl. No.: 18/249,587

(22) PCT Filed: Oct. 22, 2021
(86) PCT No.: PCT/CL2021/050104

§ 371 Date: May 24, 2023

(30) Foreign Application Priority Data
Oct. 23, 2020 (CL) 2762-2020

(51) Int. Cl. G01R 31/3842; G01R 31/371; H01M 10/42; H01M 10/48; H01M 10/44

(52) U.S. Cl. CPC G01R 31/3842; G01R 31/371; H01M 10/425; H01M 10/486; H01M 10/441; H01M 2010/4278

(57) ABSTRACT

Method of monitoring and controlling a rechargeable battery, by measuring the voltage of at least one cell, arranged inside the rechargeable battery; measuring the current, the temperature of the cell; sending the data on voltage, current and temperature, towards the control, monitoring and communication unit; determining a charge state of the cell; determining a state of health, determining an estimated charging time, determining an estimated discharging time, determining an estimated time of replacement of the cell; storing in the control, monitoring and communication unit the obtained data; sending the obtained data; displaying, comparing the obtained data with the range of preset values for each of them; evaluating to initiate the preventive action and/or a corrective action, carrying out the action; and using the obtained data in the evaluation of future preventive and/or corrective actions.

The present invention relates to a method of monitoring and controlling the state variables of at least one rechargeable battery, predicting and/or detecting faults and/or operational problems therein, thereby allowing the initiation of respective preventive and/or corrective actions in one or more of said rechargeable batteries, providing more precise and real-time monitoring and control of each of the batteries that make up a battery bank.

In this regard, the method of the invention essentially comprises the steps of measuring the voltage of at least one cell, arranged inside the rechargeable battery, by means of at least one protection and balancing unit, comprising at least one voltage sensor; measuring the current of the at least one cell, by means of the at least one protection and balancing unit, comprising at least one current sensor; measuring the temperature of the at least one cell, by means of the at least one protection and balancing unit, comprising at least one temperature sensor; and sending from the at least one protection and balancing unit at least one of the voltage, current and temperature data, towards the at least one control, monitoring and communication unit.

Furthermore, the method comprises determining a charge state, a state of health, an estimated charging time, an estimated discharging time, and an estimated time of replacement of the at least one cell, by the at least one control, monitoring, and communication unit, using at least one of the voltage, current, and temperature data of the at least one cell; storing in the at least one control, monitoring, and communication unit at least one of the voltage, current, temperature, sending from the at least one control, monitoring, and communication unit at least one of the data on voltage, current, temperature, charge state, state of health, estimated charging time, estimated discharging time, and estimated time of replacement, to the at least one management device; and displaying at least one of the data on voltage, current, temperature, charge state, state of repair, state of health, estimated charging time, estimated discharging time and estimated time of replacement for the at least one cell, by means of the at least one display device.

The method also comprises comparing, by the at least one control, monitoring and communication unit and/or by the at least one management device, at least one of the obtained data on voltage, current, temperature, charge state, state of health, estimated charging time, estimated discharging time and estimated time of replacement with at least one range of preset values for each of them in the at least one control, monitoring and communication and in the at least one management device; assessing whether it corresponds to initiate at least one preventive action and/or a corrective action in the at least one cell, by means of the at least one control, monitoring and communication unit and/or by means of the at least one management device; if it corresponds to initiate at least one preventive and/or corrective action, carrying out said preventive and/or corrective action in the at least one cell by means of the at least one control, monitoring and communication unit and/or by means of at least one management device; and using at least one of the data on voltage, current, temperature, charge state, state of health, estimated charging time, estimated discharging time and estimated time of replacement for the at least one cell, in evaluating future preventive and/or corrective actions in said at least one cell by the at least one control, monitoring and communication unit and/or by the at least one management device.

The preventive actions and/or corrective actions that the method can carry out comprise, inter alia, regulating the flow of energy entering or exiting the at least one cell, by means of the at least one energy regulating element, comprised by the at least one protection and balancing unit.

The invention also relates to a rechargeable battery and a rechargeable power supply system, which implement the method of the invention.

### BACKGROUND

Today, one of the usual solutions in industries that produce and/or are supplied by renewable energies is related to the use of electric accumulators composed of one or more rechargeable batteries to store said renewable energy, given their simplicity in implementation and their cost. During the last decades the batteries commonly used for this type of solution have been those of deep cycle. However, at present, new technologies are emerging, which are increasingly less expensive compared to the usual solutions, where lithium cell-based batteries have managed to position themselves competitively in the market for rechargeable batteries and in that of renewable energies, capturing a large percentage thereof.

In this sense, both lithium and traditional lead batteries have only energy storage as their main functionality, so any other functionality that is wanted to be delivered must be added to the outside of it, either by equipment or instrumentation.

This causes the current solutions of rechargeable batteries to present several problems when configured in banks, which so far have not been able to be satisfactorily solved. One of them is related to the impossibility of monitoring and controlling the operation of each of the batteries of the bank individually, where current solutions only provide the possibility of monitoring a certain amount of batteries of the bank and/or obtaining average operating parameters for the entire bank, by means of additional equipment that is connected to the battery bank via cables usually. This prevents the user or holder operator from knowing the state of each of the batteries of the bank, so, in the event of a problem in the operation of one or more of the batteries of the bank, it will not be able to have the information about which is the battery or batteries affected by the problem, having only partial information about the operation of the entire bank. In these situations, the user has the possibility to check the batteries of the bank one by one, however, in situations where the bank has hundreds of batteries, this option is not viable due to the amount of time, human resources and money involved by said inspection. Therefore, the user must finally opt for the replacement of the entire battery bank, which turns out to be cheaper than performing expensive inspections.

Another problem affecting battery banks at present relates to how to maintain the same level of charge in each of them, so as to avoid deterioration or accelerated aging in one or more batteries, which leads to the lifetime of the entire bank being significantly reduced. This is because batteries with a lower charge level will cause the remainder of the batteries to be discharged to compensate for their low charge level, causing the charging and discharging cycles to be carried out at a different frequency in each of the batteries, which ultimately translates into a malfunction of the entire bank. In these cases, the user or holder operator must choose the complete replacement of the bank, since banks that present these problems end up with practically all their batteries with different levels of aging, making it impossible to reuse them altogether.

Although there are external equipment that are in charge of the charge control in the current battery banks, these are only able to monitor a limited number of batteries, because most of these equipment operate through cable connections to the batteries, being therefore not able to monitor banks that have tens or hundreds of batteries, such as the banks used in the renewable energy industry (tens and hundreds of banks), which causes partial control of the bank, since the possibility of wiring the entire bank to place multiple charge controllers is not viable given the extension of cables that would have to be used through the bank, which makes it difficult the installation, operation and maintenance of the batteries, in addition to increasing the risks of accidents.

Therefore, a monitoring performed in real time and individually for each of the batteries of a battery bank would allow filling information gaps and measuring other variables in addition to current and voltage, so as to detect in a timely and precise manner any inconvenience that may be affecting one or more of said batteries, thus helping in taking preventive and/or corrective actions for the batteries that present problems, not interrupting the operation of the entire bank, maximizing its operating time. In addition, there is a need for a method and system that allows, in addition to monitoring a battery bank, controlling each of these batteries that make up the bank, in order to maximize their lifetime, by adjusting the state variables in each of the batteries in real time, such as the level of charge or discharge in each of them, so as to maintain the same charge state and state of health throughout the bank, which would allow all the batteries to age at the same rate, said information being available at all times to the user or holder operator, without the need to have additional equipment arranged externally to the bank.

In the field of patents there are also solutions aimed at monitoring and controlling battery banks. For example, US patent U.S. Pat. No. 9,979,202B2 describes a control, protection and energy management system for an energy storage system, comprising an interface configured to communicate and provide energy exchange with a host power system, a local charge, and the energy storage system. Further, it comprises a processing structure configured to receive signals from the host energy system and the energy storage system, to determine an operation mode of the energy storage system, and to provide control, protection, and energy management to the energy storage system. In this sense, the system described by this document differs from the present invention in several aspects, the most relevant being the ability of each battery to act as an independent entity within the battery bank, without the need for additional external equipment, which allows monitoring and controlling each of the batteries in real time, either by means of a monitoring, control and communication unit, arranged in each of them or by means of a management device arranged remotely to the battery bank, which receives all the operation information of each of the batteries of the bank.

Another example is that disclosed in U.S. Pat. No. 9,640,843B2, which describes an isolation apparatus, including an isolation circuitry that comprises multiple semiconductor switches arranged electrically in parallel to isolate, from an electrical system, a plurality of battery cells of a battery capable of providing high levels of current. The apparatus includes a microcontroller operatively coupled to the isolation circuitry, wherein the battery cells are isolated from the electrical system to which the battery is connected when the microcontroller switches off the multiple semiconductor switches. The apparatus provides cell-balancing, circuit isolation, trace matching, split columns, heat-tied use of materials and slow-speed switching to provide safety through isolation, equalization and stress reduction.

In this case, once again the difference that exists between the present invention and the battery management system described in document U.S. Pat. No. 9,640,843B2 lies in the non-use of apparatus or systems external to the batteries for carrying out the monitoring and control tasks, since each of them has the necessary means to monitor and control its operating variables in real time, in order to optimize the operation and lifetime of the entire bank, either through each of the batteries or through a management system arranged remotely to the battery bank, which receives all the operating information from each of the batteries of the bank. In addition, in the system described by patent U.S. Pat. No. 9,640,843B2 the apparatuses must be connected to the bank via cables, since it is not possible for the batteries to send the information on their operating parameters wirelessly, which makes installation expensive, as well as limits the number of batteries that can be connected to the management system. Finally, another important difference between the present invention and document U.S. Pat. No. 9,640,843B2 relates to the way of controlling the flow of energy, wherein said document only has the ability to cut off the flow of energy to or from a battery, not so in the present invention, wherein each battery can regulate the level of flow of energy entering or leaving it, in addition to having the possibility of completely cutting off the flow of energy if necessary. This difference is very important, since it allows the invention to provide a much greater control capacity, compared to the existing solutions, which only provide a binary control, where there is or there is no battery flow from or to the controlled battery, without the regulation capacity.

Therefore, it is necessary to have a method and system that is not only capable of monitoring the operation of a limited number of batteries within a bank, but that has the ability to monitor and control each of the batteries of the bank in a particular way and in real time, without the need to have external apparatus or systems, allowing the user or holder operator to detect early any problem that indicates the need to perform maintenance and/or repair on one or more batteries of the bank. In addition, it is necessary to have a method and system that can control the operating variables of each of the batteries of a bank, either by commands executed through each of the batteries or received externally by a remote management system, which allows maintaining within normal ranges of operation each of the operating variables in each of the batteries, thus maximizing the lifetime of the entire bank. This and other advantages associated with further aspects of the technology are described in greater detail below.

### DESCRIPTION OF THE INVENTION

The invention relates to a method and system for monitoring and controlling the state variables of at least one rechargeable battery, which allows to anticipate and/or detect faults and/or operating problems therein, thus allowing to initiate the respective preventive and/or corrective actions in one or more of said rechargeable batteries, providing a more precise and real-time monitoring and control of each of the batteries that make up a battery bank.

In addition, the present invention provides a method, battery and system that is improving its accuracy in the indication of preventive and/or corrective actions over time, due to the continuous storage of the information and data obtained over time, with which the battery and the system are fed back and learned for future indications of preventive and/or corrective actions.

The features and advantages mentioned for the present invention allow the real-time monitoring of all the variables that affect the operation of a battery, delivering vital information to the user or holder of the battery for decision making regarding the best time to perform a maintenance, repair or replacement thereof, where a fundamental difference between the prior art monitoring and control systems and the present invention is related to the impossibility of the former to be able to individually monitor each battery of a battery bank, having to resort to external devices that most of the time only deliver average parameters of the bank but not of each individual battery, making it impossible for the user or holder to identify the origin of a fault, which would allow the repair or replacement only of the battery or batteries presenting the fault.

In the case of the present invention that is totally feasible, since due to each battery of the bank monitors its main operating parameters, the user or holder receives an alert in case it is detected that it is time to perform a maintenance, repair or replacement of one or more batteries of the battery bank, thereby avoiding a classic problem of the prior art, where the user of the battery bank ends up choosing to replace the entire bank when an operating problem is found in it, since detecting the origin of a fault is a generally expensive and time-consuming process, making the complete replacement of the bank economically more viable, which does not cease to have a non-negligible cost for the user.

All of the above finally allows to maximize the lifetime of the batteries of the battery bank until reaching the theoretical times calculated by the manufacturers, since, by maintaining the different variables of each of the batteries at the same level in real time, particularly the parameters related to charge state and state of health, the problems associated with imbalances and premature aging, causing the decrease of the lifetime of the battery banks, are avoided.

In this regard, according to a first preferred embodiment of the invention, the method of monitoring and controlling at least one rechargeable battery comprises the following steps:
measuring the voltage of at least one cell, arranged inside the rechargeable battery, by means of at least one protection and balancing unit, comprising at least one voltage sensor;
measuring the current of the at least one cell, by means of the at least one protection and balancing unit, comprising at least one current sensor;
measuring the temperature of the at least one cell, by means of the at least one protection and balancing unit, comprising at least one temperature sensor;
sending from the at least one protection and balancing unit at least one of the voltage, current and temperature data to the at least one control, monitoring and communication unit;
determining a charge state of the at least one cell, by the at least one control, monitoring and communication unit, using at least one of the voltage, current and temperature data of the at least one cell;
determining a state of health of the at least one cell, by the at least one control, monitoring and communication unit, using at least one of the voltage, current and temperature data of the at least one cell;
determining an estimated charging time of the at least one cell, by the at least one control, monitoring and communication unit, using at least one of the voltage, current and temperature data of the at least one cell;
determining an estimated discharging time of the at least one cell, by the at least one control, monitoring and communication unit, using at least one of the voltage, current and temperature data of the at least one cell;
determining an estimated time of replacement of the at least one cell, by the at least one control, monitoring and communication unit, using at least one of the voltage, current and temperature data of the at least one cell;
storing in the at least one control, monitoring and communication unit at least one of the data on voltage, current, temperature, charge state, state of health, estimated charging time, estimated discharging time and estimated time of replacement;
sending from the at least one control, monitoring and communication unit at least one of the data on voltage, current, temperature, charge state, state of health, estimated charging time, estimated discharging time and estimated time of replacement, to the at least one management device;
displaying at least one of the data on voltage, current, temperature, charge state, state of health, estimated charging time, estimated discharging time and estimated time of replacement for the at least one cell, by at least one display device;
comparing, by the at least one control, monitoring and communication unit and/or by the at least one management device, at least one of the obtained data on voltage, current, temperature, charge state, state of health, estimated charging time, estimated discharging time and estimated time of replacement with at least one range of preset values for each of them in the at least one control, monitoring and communication unit and in the at least one management device;
assessing whether it corresponds to initiate at least one preventive action and/or a corrective action in the at least one cell, by means of the at least one control, monitoring and communication unit and/or by means of the at least one management device;
if it is appropriate to initiate at least one preventive and/or corrective action, carrying out said preventive and/or corrective action in the at least one cell by the at least one control, monitoring and communication unit and/or by the at least one management device; and
using at least one of the data on voltage, current, temperature, charge state, state of health, estimated charging time, estimated discharging time and estimated time of replacement for the at least one cell, in evaluating future preventive and/or corrective actions in said at least one cell by the at least one control, monitoring and communication unit and/or by the at least one management device;
   wherein initiating at least one preventive action and/or a corrective action at least comprises:
regulating the flow of energy entering or leaving the at least one cell, by means of the at least one energy regulating element, comprising the at least one protection and balancing unit.

The method of the invention is carried out due to the protection and balancing unit and the control, monitoring and communication unit, comprised by each of the rechargeable batteries possessed by the battery bank of the user. This allows real-time measurements to be obtained about the most important operating variables for each of the batteries owned by the bank. From the variables obtained by the protection and balancing unit it is possible to determine state parameters of each of the batteries of the bank in real time.

All information regarding operating variables and state parameters of each of the batteries is sent by each of the respective control, monitoring and communication units to at least one management device, which may be located in the vicinity of or remotely from the battery bank. The control, monitoring and communication unit, as well as the management device are able to analyze the operating variables and battery state parameters, comparing the information obtained with preset value ranges for each of them, in order to evaluate the need to perform a preventive and/or corrective action on the battery.

Being able to rely on the analysis of the operating variables and state parameters by each of the control, monitoring and communication units of each of the batteries of the bank, as well as by the management device, which receives all the information from each of the batteries, allows, on the one hand, that each of the batteries is able to manage itself, evaluating the need to take any preventive and/or corrective action, and, on the other hand, facilitates the evaluation of preventive and/or corrective actions that must be taken for the entire bank or for a certain number of batteries, due to the fact that all the information for each of the batteries of the bank is received by the management device.

In addition, all information about the operating variables and state parameters, together with decisions about preventive and/or corrective actions is stored, both by the control, monitoring and communication unit of each of the batteries of the bank, and by the management device. This allows to continuously feed a machine learning algorithm that the system has, which helps to improve the precision in decision making for future preventive and/or corrective actions by the control, monitoring and communication unit and the management device, either for a battery or for a group of them within the bank.

Among the preventive and/or corrective actions that can be carried out, the possibility that the system has of regulating the flow of energy entering or leaving the at least one cell, by means of at least one energy regulating element, stands out, wherein the command to vary said flow of energy can come from the at least one control, monitoring and communication unit, and/or from the at least one management device. This allows the charge state for each of the batteries of the bank to be regulated, so as to ensure that all the batteries of said bank are in the same level of charge and state of health, which helps to improve the performance of the battery bank, increasing its lifetime.

A display device, which may be arranged on each of the batteries and/or be part of the rechargeable power supply system of the invention, displays all the information regarding the operating variables of the battery and the state parameters, so that the user of the system knows in real time the state of each of the batteries of the battery bank. In addition, the management device is able to display the information for each of the batteries of the bank through the display device, as well as additional information of the overall operation of said bank, determined through all the information received by each of the batteries of the bank.

This is a great advantage over traditional monitoring and control systems, since the user or holder operator of the system is able to know in real time the state of each of the batteries of the bank from anywhere, thus avoiding having to intervene the bank with a large number of additional elements and devices to be able to know the state of the bank.

According to another embodiment of the invention, the method further comprises issuing an audible alert, by at least one audible alarm, in case that at least one of the data on voltage, current, temperature, estimated charging time, and estimated discharging time are outside of the at least one preset range for each of them.

The audible alarm is located inside each of the batteries of the bank, wherein said audible alert allows, in the event of a problem due to some anomaly in the measured operating variables and/or determined state parameters, to alert the user and/or the people who may be in the vicinity of the battery bank so that they approach to check the detected situation.

According to another embodiment of the invention, the method further comprises sending an alert from the at least one control, monitoring and communication unit and/or from the at least one management device, to the at least one display device, in case that at least one of the data on voltage, current, temperature, estimated charging time and estimated discharging time are outside of the at least one preset range for each of them.

As in the case of the audible alert, the control, monitoring and communication unit of each of the batteries, as well as the management device, are able to send an alert to be displayed by the user or operator maintaining the system in case an anomaly is detected in the values of one or more of the operation variables and/or of the determined state parameters. As mentioned above, this is an advantage over traditional monitoring and control systems, since, in real time, the user or operator maintaining the system knows the individualized state of each of the batteries of the bank, where, upon receiving an alert from the control, monitoring and communication unit or part of the management device, he/she will immediately know which is the batteries that present problems, being able to take the corresponding measures quickly and efficiently, avoiding having to intervene the entire battery bank to find the problem.

According to another embodiment of the invention, the method further comprises, in case that at least one of the current, voltage and temperature data for the at least one cell is outside the at least one preset range for each of them, cutting the connection between the at least one rechargeable battery and the outside, by at least one disconnecting element, and placing the at least one at least one rechargeable battery in the alert state, by the at least one control, monitoring and communication unit and/or by the at least one management device.

This allows, in case for some reason one or more of the current, voltage and/or temperature values are outside previously set parameters, according to the operating and/or environmental conditions of the place where the bank is located, such as for example, a current overcharge, to proceed to disconnect the battery from the outside preventively through its disconnecting element, in order to prevent its components from being damaged. In addition, the battery enters an alert state to be able to activate the audible alarm and/or send an alert message, through the control, monitoring and communication unit, to the management device and/or to the display device, to be displayed by the user or operator maintaining the system, so that corresponding corrective measures are taken.

According to another embodiment of the invention, regulating the flow of energy entering or leaving the at least one cell, by the at least one energy regulating element, is performed between an open and closed state.

This embodiment of the invention allows the energy regulating element to act in a binary manner, i.e. only allowing two states for energy input or output from the at least one cell, wherein either there is no energy input or output, or the energy flow is not limited in any way to or from the at least one cell.

According to another embodiment of the invention, regulating the flow of energy entering or exiting from the at least one cell, by the at least one energy regulating element, is performed between 0% energy flow entering or exiting to 100% energy entering or exiting.

From this embodiment of the invention, it is possible to regulate the energy input or output from the at least one cell in any percentage that is necessary, according to the charge or discharge needs of the moment.

According to another embodiment of the invention, the method further comprises, in case the charge state data for the at least one cell is below the at least one preset range, during a charging process of the at least one rechargeable battery:
increasing the flow of energy to the at least one cell in which the charge state data is below the at least one preset range, by its at least one energy regulating element.

According to another embodiment of the invention, the method further comprises, in case the charge state data for the at least one cell is below the at least one preset range, during a charging process of the at least one rechargeable battery:
establishing communication between the at least one control, monitoring and communication unit and at least one other control, monitoring and communication unit associated with another rechargeable battery; or
establishing communication between the at least one control, monitoring and communication unit and the at least one management device, such that it establishes communication with at least one other control, monitoring and communication unit associated with another rechargeable battery; or
establishing a communication, by the management device, between the at least one control, monitoring and communication unit with at least one other control, monitoring and communication unit associated with another rechargeable battery;
decreasing the flow of energy to the at least one cell in the other rechargeable battery, by its at least one energy regulating element; and increasing the flow of energy to the at least one cell in which the charge state data is below the at least one preset range, by its at least one energy regulating element.

According to another embodiment of the invention, decreasing the flow of energy to the at least one cell in the other rechargeable battery, by its at least one energy regulating element; and increasing the flow of energy to the at least one cell in which the charge state data is below the at least one preset range, by its at least one energy regulating element, are performed until the charge state data for the at least one cell in which the charge state data is below the at least one preset range is again within the at least one preset range.

According to another embodiment of the invention, the method further comprises, in case the charge state data for the at least one cell is within or above the at least one preset range, during a charging process of the at least one rechargeable battery:
establishing communication between the at least one control, monitoring and communication unit and at least one other control, monitoring and communication unit associated with another rechargeable battery; or
establishing communication between the at least one control, monitoring and communication unit and the at least one management device, such that it establishes communication with at least one other control, monitoring and communication unit associated with another rechargeable battery; or
establishing a communication, by the management device, between the at least one control, monitoring and communication unit with at least one other control, monitoring and communication unit associated with another rechargeable battery;
decreasing the flow of energy to the at least one cell in which the charge state data is within or above the at least one preset range, by its at least one energy regulating element; and
increasing the flow of energy to the at least one cell in the other rechargeable battery, by its at least one energy regulating element.

According to another embodiment of the invention, decreasing the flow of energy to the at least one cell in which the charge state data is within or above the at least one preset range, by its at least one energy regulating element; and increasing the flow of energy to the at least one cell in the other rechargeable battery, by its at least one energy regulating element, are performed until the charge state data for the at least one cell in which the charge state data is within or above the at least one preset range is again within the at least one preset range.

The last four mentioned embodiments for the method of the invention are fundamental to achieve that the charge state of each of the batteries of the battery bank is at a same level when the batteries of the bank are in a process of recharging energy, since, in case the charge state of any of the batteries is under a preset range or value, for example, the average value of the charge state of the entire battery bank in real time, the control, monitoring and communication unit is able to communicate with other batteries of the bank that are at or above the preset range or value for the charge state, so that said one or more batteries with a higher energy level are configured through commands sent by their respective control, monitoring and communication units to their energy regulating elements to receive a lower amount of energy per unit of time, thus allowing the battery with a lower charge state receives a greater flow of energy, also due to the command sent by its control, monitoring and communication unit to its energy regulating element, in order to achieve that all are with the same level of charge state.

This is another technical advantage of the present invention with respect to traditional control and monitoring systems, since all of them operate externally to the batteries, where many times they cannot obtain the charge state for each of the batteries individually, but obtain the average value for the entire bank or part thereof, so it is not possible to detect if the charge state of any of the particular batteries is at a lower level than the rest. Due to the embodiments described by the present invention, it is possible to maintain all the batteries with the same charge state at all times, substantially increasing the lifetime of each one of them and therefore of the battery bank.

In addition, by keeping all the batteries with the same charge state, these age uniformly, extending the lifetime of the battery bank, but not in traditional battery banks, where some batteries age before others due to their different charge states, thereby decreasing the lifetime of the entire battery bank.

According to the four embodiments just described, there is also the possibility that the control, monitoring and communication unit of the battery that is in a charge state lower than the set value or range, communicates with the management device, so that it is the one that locates the batteries that have a charge state at or above the set range, so as to command them to decrease the flow of energy they receive, thus increasing the flow of energy towards the battery with a lower charge state in the manner detailed above, until they are all within the set range, so that the entire bank can be maintained with the same charge state at all times.

Finally, the four embodiments just described also allow the possibility that it is directly the management device that detects the need to regulate the charge in one or more cells in one or more of the batteries of the bank, said element establishing the communication between the respective control, monitoring and communication units that must give the orders to regulate the flow of energy they receive.

According to another embodiment of the invention, the method further comprises, in case the charge state data for the at least one cell is below the at least one preset range, during a discharging process of the at least one rechargeable battery:
decreasing the flow of energy being discharged from the at least one cell in which the charge state data is below the at least one preset range, by its at least one energy regulating element.

According to another embodiment of the invention, the method further comprises, in case the charge state data for the at least one cell is below the at least one preset range, during a discharging process of the at least one rechargeable battery:
establishing communication between the at least one control, monitoring and communication unit and at least one other control, monitoring and communication unit associated with another rechargeable battery; or
establishing communication between the at least one control, monitoring and communication unit and the at least one management device, such that it establishes communication with at least one other control, monitoring and communication unit associated with another rechargeable battery; or
establishing a communication, by the management device, between the at least one control, monitoring and communication unit with at least one other control, monitoring and communication unit associated with another rechargeable battery;
increasing the flow of energy that is discharged from the at least one cell into the other rechargeable battery, by its at least one energy regulating element; and decreasing the flow of energy that is discharged from the at least one cell in which the charge state data is below the at least one preset range, by its at least one energy regulating element.

According to another embodiment of the invention, increasing the flow of energy being discharged from the at least one cell into the other rechargeable battery, by its at least one energy regulating element; and decreasing the flow of energy being discharged from the at least one cell in which the charge state data is below the at least one preset range, by its at least one energy regulating element, are performed until the charge state data for the at least one cell in which the charge state data is below the at least one preset range is again within the at least one preset range.

According to another embodiment of the invention, the method further comprises, in case the charge state data for the at least one cell is within or above the at least one preset range, during a discharge process of the at least one rechargeable battery:
establishing communication between the at least one control, monitoring and communication unit and at least one other control, monitoring and communication unit associated with another rechargeable battery; or
establishing communication between the at least one control, monitoring and communication unit and the at least one management device, such that it establishes communication with at least one other control, monitoring and communication unit associated with another rechargeable battery;
establishing a communication, by the management device, between the at least one control, monitoring and communication unit with at least one other control, monitoring and communication unit associated with another rechargeable battery;
increasing the flow of energy being discharged from the at least one cell in which the charge state data is within or above the at least one preset range, by its at least one energy regulating element; and
decreasing the flow of energy being discharged from the at least one cell in the other rechargeable battery, by its at least one energy regulating element.

According to another embodiment of the invention, increasing the flow of energy being discharged from the at least one cell in which the charge state data is within or above the at least one preset range, by its at least one energy regulating element; and decreasing the flow of energy being discharged from the at least one cell into the other rechargeable battery, by its at least one energy regulating element, are performed until the charge state data for the at least one cell in which the charge state data is below the at least one preset range is again within the at least one preset range.

The last four embodiments of the invention aim at the charge balance between the batteries of the battery bank when it is in a discharge process, for which the method functions in an analogous manner to that recited for the case when the bank is in a charging process, also having the advantages already mentioned for said case in which the bank is being charged.

According to another embodiment of the invention, the method further comprises, in case the charge state data for the at least one cell is at its maximum value, stopping the flow of energy to the at least one cell, by the at least one energy regulating element. This mode allows the battery to no longer receive energy, which can be used for other batteries that are not yet fully charged.

According to another embodiment of the invention, the method further comprises, in case the charge state data for the at least one cell is at or below a minimum value, stopping the flow of energy discharged from the at least one cell, by the at least one energy regulating element.

Due to this embodiment of the invention, it is possible to protect the cells of each of the batteries of the bank so that they are not discharged beyond a set level, which may vary depending on the number of batteries of the bank and/or the time that the battery has been operating, thus preventing these from being damaged, helping to extend the lifetime of the cells of each of the batteries of the bank.

According to another embodiment of the invention, the method further comprises, in case the charge state data for the at least one cell is at or below the minimum value, emitting an audible alert by the at least one audible alarm.

According to another embodiment of the invention, the method further comprises, in case the charge state data for the at least one cell is at or below the minimum value, sending an alert from the at least one control, monitoring and communication unit and/or from the at least one management device, towards the at least one display device.

The two embodiments just described allow the user or holder operator of the battery bank to know in real time if one or more of the batteries has reached a minimum charge level, so that he can check if the causes of said low energy level are due to a decrease in the production of electrical energy in the source that recharges the batteries, to an overconsumption by the sources powered by the battery bank or to a failure in the bank.

According to another embodiment of the invention, the method further comprises, in case the data of state of health for the at least one cell is below the at least one preset range, decreasing charge/discharge cycles in the at least one cell, by the at least one control, monitoring and communication unit and/or by the at least one management device, until the data of state of health for the at least one cell is within the at least one preset range.

According to another embodiment of the invention, the method further comprises, in case the data of state of health for the at least one cell is above the at least one preset range, increasing the charge/discharge cycles in the at least one cell, by the at least one control, monitoring and communication unit and/or by the at least one management device, until the data of state of health for the at least one cell is within the at least one preset range.

These two embodiments of the invention allow the use of batteries with different states of health or, in other words, with different degrees of aging, since the method of the invention allows to regulate the battery bank so that all of them reach the same levels in terms of their states of health, causing the bank to age uniformly, thus extending the lifetime of said bank, something that none of the solutions existing in the prior art is able to perform.

According to another embodiment of the invention, the method further comprises, in case the data of state of health for the at least one cell is at or below the minimum value, emitting an audible alert by the at least one audible alarm.

According to another embodiment of the invention, the method further comprises, in case the data of state of health for the at least one cell is at or below its minimum value, sending an alert from the at least one control, monitoring and communication unit and/or from the at least one management device, towards the at least one display device indicating the need for inspection for the at least one cell.

Due to this embodiment of the invention, it is possible for the user or holder operator of the battery bank to immediately know whether one or more batteries of the bank should be inspected, thereby decreasing the chances of having a major failure in the bank due to a particular problem in one or more of the batteries.

Furthermore, according to a preferred embodiment of the invention, the method further comprises, in case the data of state of health for the at least one cell is at or below its minimum value, stopping the flow of energy being received or discharged from the at least one cell, by the at least one energy regulating element, and placing the at least one at least one rechargeable battery in an alert state, by the at least one control, monitoring and communication unit and/or by the at least one management device.

According to another embodiment of the invention, the method further comprises, in case the data on estimated time of replacement for the at least one cell is below the at least one preset range, decreasing a charge/discharge cycles in the at least one cell until the data on estimated time of replacement for the at least one cell is within the at least one preset range, by the at least one control, monitoring and communication unit and/or by the at least one management device.

According to another embodiment of the invention, the method further comprises, in case the data on estimated time of replacement for the at least one cell is above the at least one preset range, increasing charge/discharge cycles in the at least one cell until the data on estimated time of replacement for the at least one cell is within the at least one preset range, by the at least one control, monitoring and communication unit and/or by the at least one management device.

According to another embodiment of the invention, the method further comprises, in the event that the data on estimated time of replacement for the at least one cell is at or below a minimum value, emitting an audible alert by the at least one audible alarm.

According to another embodiment of the invention, the method further comprises, in case the data on estimated time of replacement for the at least one cell is at or below its minimum value, sending an alert from the at least one control, monitoring and communication unit and/or from the at least one management device, towards the at least one display device indicating the need for replacement for the at least one cell.

Knowing the estimated time of replacement for each of the batteries that make up a battery bank allows the user or holder operator of the battery bank to immediately know if one or more batteries of the bank must be replaced, thus decreasing the time in which the energy storage capacity of the bank is affected, due to which it is possible to proceed quickly with the necessary replacements.

Furthermore, according to a preferred embodiment of the invention, the method further comprises, in case the data on the estimated time of replacement for the at least one cell is at or below its minimum value, stopping the flow of energy being received or discharged from the at least one cell, by the at least one energy regulating element, and placing the at least one at least one rechargeable battery in an alert state, by the at least one control, monitoring and communication unit and/or by the at least one management device.

According to another embodiment of the invention, the method further comprises measuring the impedance of the at least one cell, by the at least one protection and balancing unit, comprising at least one impedance sensor.

According to another embodiment of the invention, the method further comprises measuring the humidity outside the at least one cell, by means of the at least one protection and balancing unit, comprising at least one humidity sensor.

According to another embodiment of the invention, the method further comprises measuring the salinity on the outside of the at least one cell, by means of the at least one protection and balancing unit, comprising at least one salinity sensor.

According to another embodiment of the invention, at least one of the steps of determining a charge state, determining a state of health, determining an estimated charging time, determining an estimated discharging time, and determining an estimated time of replacement, for the at least one cell, by the at least one control, monitoring and communication unit, further comprises using at least one of the impedance, humidity and salinity data of the at least one cell.

According to another embodiment of the invention, the method further comprises measuring vibrations in the rechargeable battery, by means of a vibration sensor. This allows monitoring each of the batteries in the event that they suffer a fall, an object falls on them or have an unexpected displacement.

According to another embodiment of the invention, the method further comprises monitoring the position of the rechargeable battery, by means of a locating element, which allows the user or holder operator to know the location of each of the batteries of the bank, in the event of one or more of them are stolen by a third party.

According to another embodiment of the invention, the method further comprises measuring the pressure inside the rechargeable battery, by means of a pressure sensor. Sometimes, due to a malfunction of the battery, there may be generation or leakage of gases from the cells, which can increase the pressure inside the battery, which is usually hermetically sealed. This can be dangerous and can cause a battery explosion. For this reason, it is important to have a pressure sensor that monitors this condition in each of the batteries of the bank.

According to another embodiment of the invention, the method further comprises monitoring the opening and closing of an outer casing of the rechargeable battery, by means of an opening sensor. This allows only authorized personnel to have access to the inside of the batteries of the battery bank, for the performance of maintenance and/or repair tasks.

According to another embodiment of the invention, the method further comprises comparing at least one of the obtained data on vibrations, position, pressure and opening and closing of the outer casing with at least one range of preset values for each of them in the at least one control and monitoring unit and in the at least one management device.

According to another embodiment of the invention, the method further comprises, in the event of one or more of the data on vibrations, position, pressure and opening and closing of the outer casing are outside the at least one range of preset values for each of them, emitting an audible alert by the at least one audible alarm.

According to another embodiment of the invention, the method further comprises, in the event of one or more of the data on vibrations, position, pressure and opening and closing of the outer casing are outside the at least one range of preset values for each of them, sending an alert from the at least one control, monitoring and communication unit towards the at least one display device.

Being able to count on audible alerts or through the display device allows the user or holder operator to know immediately in the event that something unexpected occurs with one or more of the batteries of the battery bank, allowing immediate measures to be taken if necessary, for example, in the event of the theft of one or more batteries by a third party or in the event that for any of them there is a risk of causing an accident.

On the other hand, according to a second preferred embodiment of the invention, a rechargeable battery comprising:
at least one outer casing;
at least two connecting elements;
at least one cell;
at least one protection and balancing unit, comprising:
at least one voltage sensor;
at least one current sensor;
at least one temperature sensor;
at least one energy regulating element; and
at least one control, monitoring and communication unit.

According to another embodiment of the invention, the battery further comprises at least one display device. Preferably, the display device is located on the outer casing of the rechargeable battery.

According to another embodiment of the invention, the at least one protection and balancing unit further comprises at least one disconnecting element.

According to another embodiment of the invention, the battery further comprises at least one audible alarm.

According to another embodiment of the invention, the battery further comprises at least one impedance sensor.

According to another embodiment of the invention, the battery further comprises at least one humidity sensor.

According to another embodiment of the invention, the battery further comprises at least one salinity sensor.

According to another embodiment of the invention, the at least one protection and balancing unit and the at least one control, monitoring and communication unit perform data communications via cables.

According to another embodiment of the invention, the at least one protection and balancing unit and the at least one control, monitoring and communication unit perform data communications via 3G, 4G, 5G, Bluetooth, infrared, radiofrequency, NFC, Wifi, LoRa, LoRaWan wireless networks or any other network that allows wireless communication.

The latter two embodiments of the invention allow the user or holder operator of the battery bank to obtain and visualize the data and parameters of said bank, either via cables, which could be useful for banks of reduced size or located in areas where wireless communication is not possible to carry out, or through wireless networks, which is useful in the event of having a bank composed of a large number of batteries, where the use of cables is not viable.

The possibility of sending the data and parameters obtained for each of the batteries of the bank through wireless networks is a feature that is not present in practically any of the existing batteries in the prior art, where, those that do possess this wireless communication capacity, can only do so for a limited number of batteries, given the energy expenditure that this form of communication implies, generally through GPRS and GSM networks. The present invention solves this problem by using wireless communication media that have a much lower energy consumption, such as LoRa, LoRaWan or radiofrequency, which are also much more economical. This is essential in batteries that work accumulating solar energy, where the accumulation capacity of generation systems must be maximized.

On the other hand, in the case of battery banks that do not have any type of wireless communication, it is the user who has to proceed to connect the batteries to external apparatuses, so as to obtain only some of the possible data for the batteries, wherein, in the event of the bank comprises tens or hundreds of batteries it will be impossible to obtain the data for all of them, since the external controlling apparatuses are configured to control only a limited number of batteries.

According to another embodiment of the invention, the battery further comprises at least one vibration sensor.

According to another embodiment of the invention, the battery further comprises at least one locating element.

According to another embodiment of the invention, the battery further comprises at least one pressure sensor.

According to another embodiment of the invention, the battery further comprises at least one opening sensor.

According to another embodiment of the invention, at least one of the impedance sensor, the humidity sensor, the salinity sensor, the vibration sensor, the locating element and the pressure sensor is comprised by the at least one protection and balancing unit.

According to another embodiment of the invention, at least one of the impedance sensor, the humidity sensor, the salinity sensor, the vibration sensor, the locating element and the pressure sensor is comprised by at least one sensor unit.

On the other hand, according to a third preferred embodiment of the invention, there is also described a rechargeable power supply system, comprising:
at least one rechargeable battery
at least one management device; and
at least one display device

In view of the above description, it is relevant to note that the present invention, through its various preferred configurations, is not only able to anticipate and detect failures in the operation of one or more batteries, but also has the ability to manage or manage the energy in each of them, i.e. decide whether to supply energy or not, how much energy to deliver, for how long to deliver energy, at what rate the energy should be delivered, etc. These features associated with the management or administration of energy in each of the batteries of the battery bank is a key difference in relation to the Battery Management System (BMS) that have some of the current solutions implemented in battery banks, which, although they have the ability to monitor a limited number of batteries and communicate the information to a centralized management system, they are not able to manage the energy in each of the batteries they are monitoring.

The management of energy in battery banks is an issue of great relevance in banks, in which it is essential to have improvements that allow better management, such as those implemented by the present invention, which allow the balance of charges in the battery bank, which finally aims to maximize the performance of the bank. In addition, being able to manage the how, when and how much energy must be supplied by each of the batteries or consumed by the system to which it is supplied, allows to offer other benefits, such as maximizing profits or investment returns, since its use can be managed according to the sale price of electrical energy in systems that are directly connected to the electricity network, where they are only used during peak price hours, or are recharged when the price of energy is at a downstream price schedule, which can be controlled by the system management device or by the protection and balancing unit of each of the batteries of the bank in real time.

Said control in the energy management in each of the batteries of the bank depends on mathematical algorithms that allow the system to learn from the conditions of the environment in which it is operating, being feed the information collected through machine learning functions, making the system more robust and efficient in its operation as time passes. This allows the system, for the aforementioned case in which the battery bank is directly connected to the power mains, or in the case in which it is only supplying energy to charges, or in the case in which the system is operating in a mixed system, to supply different amounts of energy, depending on the requirements and/or utilities to be maximized by energy delivery. On the other hand, the user could indicate to the system the specific times of the day when the bank should be dedicated to storing energy, or to store or discharge in specific percentages for certain periods of time or at some specific time, or to send pulses of energy in a certain time range, indicating the type of pulse, which could be increasing, decreasing or sinusoidal type or other waveform.

On the other hand, the embodiments of the present invention allow the connection of batteries with different lifetime (health or longevity state), since the system has the ability to regulate the charge/discharge cycles of each of the batteries connected to the bank, from the energy management that is performed through the management device and/or through the protection and balancing unit of each of the batteries. This is a not minor feature of the present invention, since in current battery banks with different longevity states are never installed, since in that case some batteries will end their lifetime before others, with the user having to identify them one by one, which implies using large amounts of resources and time. This is one of the problems solved by the invention, due to the monitoring and control that can be carried out of each of the batteries of the bank, allowing the user to combine banks of batteries or expand them according to their particular interests.

In addition, the method and system of the invention allow to increase the lifetime of the battery bank, mainly, for the same reason explained above, due to which it is possible to maintain all the batteries of the bank with the same state of health, lifetime or longevity, thus maximizing the lifetime of the entire battery bank, since the system will regulate the charge/discharge cycles of all the batteries so that they end their lifetime at the same time, the phenomenon occurring in current battery banks not happening, wherein, despite having control apparatus or systems, the batteries begin to end their lifetime at different times, causing the entire bank to end its lifetime earlier than expected.

In relation to other advantages of the method and system of the present invention, the configurations presented allow to increase the performance of the battery bank, in comparison with the current battery banks, since each of the batteries of the bank has the ability to regulate the charge/discharge rate to balance their charge states at the same value, thus allowing to take advantage of the battery bank at its maximum operating capacity. If this function were not present and there were some batteries with different charge states, the capacity of the bank would not be the same as that specified by the manufacturer or installer, since it is conditioned to the charge state of the most unbalanced batteries, thus affecting the total capacity of the system and generating an accelerated aging in some batteries. This has the consequence that the user would not make the most of the storage capacity of the bank, leading to economic losses due to the need to install oversized banks to take care of the loss of performance.

Many users who present such problems in their battery bank conclude that their entire bank is defective, changing it to a new one, which leads these users not to take full advantage of the capabilities of their battery bank, in addition to having to incur expenses more frequently than users who keep their battery banks balanced, due to accelerated aging. Although in the case of lead-acid batteries the detection of unbalanced batteries is relatively easy, since only the voltage of each of the batteries of the bank must be measured, in lithium batteries this is not possible, since the voltage in this type of batteries is kept practically constant always, regardless of its charge state, not being possible to detect easily by the user if one or more of the batteries of the bank is unbalanced.

Due to the above it is that banks of batteries connected in parallel are not normally used, or are limited to a few branches in parallel, since each of these is discharged at different rates and, consequently, generate an internal imbalance of the bank only by the fact of being arranged in this way. This is a problem of great relevance in the renewable energy industry, which was addressed by the present invention, which provides a solution that allows controlling the charge/discharge rate of its batteries so that they are discharged at the same rate, making it possible to connect an unlimited number of batteries in parallel. This has the benefit of being able to diversify the energy flowing through the battery bank into multiple branches in parallel, which ensures the delivery of energy to the charges fed by the bank in the event of one or more of the branches in parallel suffers a failure, which does not happen in battery banks where the batteries are connected in series, in which it is sufficient for a battery to fail for the entire bank to fail, leaving the charges to be supplied without energies. In addition, the method and system of the invention allows to make battery banks of mega industrial capacity (hundreds of batteries) using smaller batteries, suitable for use both in industrial type systems and for smaller systems, of home type.

Finally, it is relevant to highlight that the algorithms used by the method and system of the present invention, with which the system is fed through machine learning functions, allows it, in addition to taking preventive and corrective actions in relation to each of the batteries connected to the bank, to obtain predictions of failures and consumptions in each of them, which makes the system increasingly robust and efficient due to its constant learning, improving its performance, optimizing the performance of preventive maintenance and decreasing the intervention of third parties in the operation of the system.

Accordingly, the present invention provides a method and system for monitoring and controlling the state variables of at least one rechargeable battery in a battery bank, which allows to predict and/or detect faults and/or operating problems in them, due to a more precise and real-time monitoring and control than that offered by the solutions currently available in the prior art, in addition to keeping each of the batteries of the bank operating in ideal conditions, thus maximizing the lifetime of the entire battery bank, which is able to always operate at its maximum capacity.

### BRIEF DESCRIPTION OF THE DRAWINGS

As part of the present invention are presented the following representative figures thereof, which teach preferred configurations of the invention and, therefore, should not be considered as limiting the definition of the claimed subject matter.

FIG. 1 shows the arrangement of a control and monitoring system of a battery bank, according to the prior art.

FIG. 2 teaches problems associated with the control and monitoring system of FIG. 1.

FIG. 3 shows a first solution to problems presented in control and monitoring systems of battery banks, according to the prior art.

FIG. 4 shows a second solution to problems presented in control and monitoring systems of battery banks, according to the prior art.

FIG. 5 shows a scheme of the control and monitoring system of a rechargeable battery bank, according to a preferred configuration of the invention.

FIG. 6 shows a first operating scheme of the control and monitoring system of a rechargeable battery bank, according to a preferred configuration of the invention.

FIG. 7 shows a second operating scheme of the control and monitoring system of a rechargeable battery bank, according to a preferred configuration of the invention.

FIG. 8 shows a third operating scheme of the control and monitoring system of a rechargeable battery bank, according to a preferred configuration of the invention.

FIG. 9 shows a fourth operating scheme of the control and monitoring system of a rechargeable battery bank, according to a preferred configuration of the invention.

FIG. 10 shows a fifth operating scheme of the control and monitoring system of a rechargeable battery bank, according to a preferred configuration of the invention.

FIG. 11 shows a sixth operating scheme of the control and monitoring system of a rechargeable battery bank, according to a preferred configuration of the invention.

FIG. 12 shows an isometric view of the rechargeable battery, according to a preferred configuration of the invention.

FIG. 13 shows an interior view of the rechargeable battery, according to a preferred configuration of the invention.

### DETAILED DESCRIPTION OF THE DRAWINGS

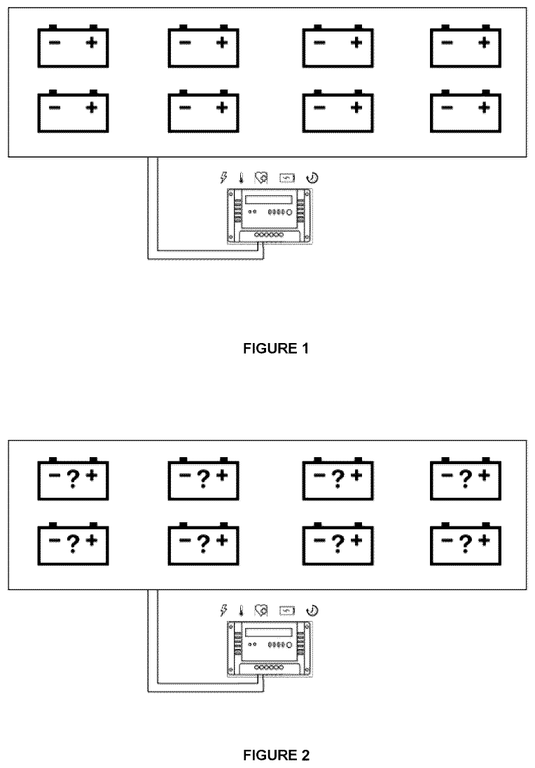

With reference to the accompanying figures, FIG. 1 shows a diagram of a solution currently used in the industry, which essentially corresponds to the use of conventional equipment, such as inverters or charge regulators, which have the ability to measure in real time some variables of a battery group, such as voltage and current, in addition to being able to estimate others, such as temperature, charge state, state of health and charging/discharging times of the battery group. Some of these equipment can also be monitored remotely via wired or wireless connection. However, the cost of these devices grows exponentially and have certain limitations, since they are closed systems that work with equipment, accessories, or batteries from the same manufacturers, where the configuration and enabling of monitoring is not easy to perform by people who are not experts in the field. For this reason, remote monitoring is generally not implemented since it is a high cost solution and also requires technical knowledge to enable it.

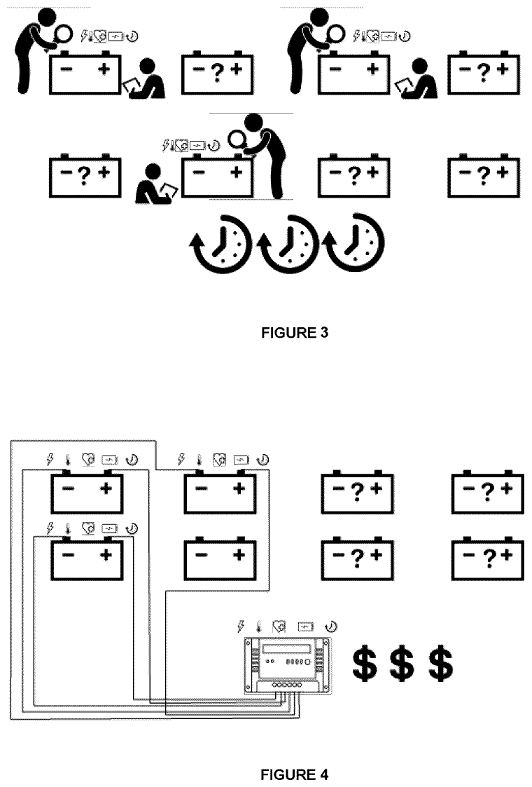

Referring to FIG. 2, this aims to visualize one of the problems of current control and monitoring systems, aimed at data misinterpretation and problem identification. The problem with measuring and estimating the state variables of an energy storage system (battery bank) is that information is usually obtained about a set of batteries and not each one specifically. This has great relevance since a misinterpretation can be generated in the reading of data, because there is variability in operation in each of the batteries, and, depending on the configuration of the connections, the bank may be conditioned to the weakest link of the chain. Having only global bank information and not about the individual state of each of the batteries, can cause erroneous conclusions from reading the data, obtaining a false sense of security, which will ultimately generate unforeseen problems, such as failures or unexpected malfunctions. For example, in a bank of two 12V batteries connected in series, this should indicate, in theory, 24V, however, in reality it could happen that each one is separately at 11V and 13V respectively, adding together 24V, which is a serious problem, since the 11V battery will be completely discharged and will condition the operation of both, where the monitoring carried out by the system will indicate that everything is “working correctly”, since it could be assumed that each one has its correct nominal voltage of 12V. Similar problems occur with the state of health and charge state of the battery bank, which can only be obtained for one group of batteries and not for each of them. Therefore, these solutions of the art are prevented from identifying point problems in an energy storage system, and, consequently, difficulties in identifying problems in the entire battery bank. The latter is relevant, since, not knowing the state of each battery in a timely manner, it is difficult to determine where the origin of the problem is. In addition, since there is no historical information on the operation of each of the batteries, it ends up being impossible to determine the cause of said problem that may be affecting the battery bank.

FIG. 3 shows a solution to the problems presented in control and monitoring systems of battery banks, according to the prior art. As mentioned above, if there is a problem with a battery-based energy storage system, if you do not have the specialized equipment or instruments, you need to investigate the origin of the problem. For these tasks, one of the most common ways is the electrical and physical inspection of each of the batteries. This is done manually one by one with a voltmeter or other manual tool, which allows you to make general voltage measurements and intuit that there is a problem. The problem that arises from this solution is that it is not possible to determine the cause and neither the origin of the problem, since it can only be intuited that there is some significant variation with respect to the rest of the battery bank, this being a “symptom” and not the origin of the problem. Given the complexity of the problem, what is done in practice is to change the defective component for a new one, which leads to the generation of other problems, such as, for example, combining batteries with different state of health, which affects the performance of the system, rapidly wearing down the batteries of the bank.

On the other hand, this battery-by-battery physical inspection solution can mean a lot of time, high cost and require field personnel. Depending on the size of the battery bank, this task is tedious and extensive, so costs are incurred not only for the inspection itself, but also for the extended stopping of the operation of the system.

In the case of lithium batteries and, in particular, lithium ferrum phosphate (LFP) batteries, the solution based on identifying the “symptom” by means of voltage measurement of each of the batteries is not a feasible solution, since due to the electrochemical nature of the batteries, the voltage remains practically constant in their charge/discharge cycle, so determining their charge state or life in the field with conventional electronic equipment turns out to be impossible and, therefore, the determination of the origin or the cause of some malfunction of the battery bank requires to be studied by highly specialized laboratory equipment to determine said variables of capacity, charge state and health.

For its part, FIG. 4 teaches another solution to the problems presented in control and monitoring systems of battery banks, according to the prior art. Among other solutions to the problem of identifying state variables of battery banks is the use of highly specialized and high-end equipment normally only found in the photovoltaic industry. For this reason, these equipment are of high price, not only for their high degree of specialization, but also for their cost of installation, since they require to be wired to each of the batteries, involving an extensive installation time and a professional electrical planning, because it is essential to have strategically organized the large distribution of cables and conductors that will be obtained when using this system, since there could be tens or hundreds of batteries for each bank. In addition, this type of solution has another big physical problem, which has to do with the fact that only a certain number of batteries can be connected to a single equipment, having to acquire several more if monitoring of the state variables of all the batteries in a battery bank is wanted, making this solution economically impossible.

An alternative to this high-end equipment is the use of apparatus, such as battery analyzers, which are laboratory instruments that can be taken to the field, to analyze the state variables of the batteries of the bank. These are mainly used when a problem is generated in the battery bank, and it is necessary to study the operation to determine the cause or origin thereof. However, this equipment is also very limited to the number of batteries to be connected and are not designed to operate at all times but in the deep study of operation when a problem is generated or as repetitive maintenance.

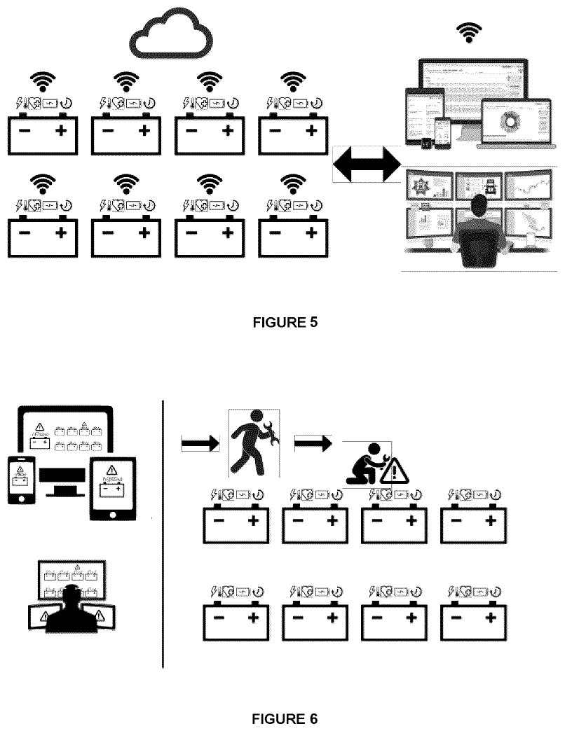

In this sense, FIG. 5 shows a scheme of the control and monitoring system of a rechargeable battery bank, according to a preferred configuration of the invention. The proposed solution consists of a system that provides batteries that have the capacity to be monitored and controlled remotely or autonomously through machine learning techniques or artificial intelligence, which has a series of associated benefits, as mentioned throughout this specification. The batteries that make up the bank have the ability to store information, or to send this information to an external management system to be stored and displayed by a user or holder operator through a display device, such as a smartphone, a computer, a tablet, etc. This allows to visualize in real time the state of each battery, as well as the historical record for each of its operating variables, which is key to be able to identify not only the origin of a malfunction, but also to be able to have the necessary tools to identify the cause. On the other hand, all the stored historical information serves to feed mathematical algorithms, fundamental for what is behavior prediction, study by means of Big Data and machine learning. It is also possible to predict, anticipate and schedule maintenance periods, starting from the use of technical data that justify them, as well as with the battery replacement period.

On the other hand, the remote and/or autonomous control of each of the batteries composing the bank allows each of them to always work within their nominal ranges, improving the safety of the battery bank and maximizing its efficiency.

FIG. 6 shows one of the modes of operation of the control and monitoring system of a rechargeable battery bank, according to a preferred configuration of the invention. Being able to count on the detail of the state of the operating variables of each of the batteries of a bank individually allows identifying a problem in a timely manner, saving significant costs and times in said identification task, solving the problem or malfunction quickly and accurately. The intelligent system provides tools that allow identifying what, how, when, where and why a malfunction or problem occurred in one or more batteries of the bank. This makes it possible to minimize the intervention on the ground by third parties, which will arrive directly at the battery(s) with problems, with a solution that is already premeditated/planned/planned in advance, reducing the intervention time, either in the identification or in the maintenance itself, as well as the operating costs associated with the stopping of battery bank.

In addition, the batteries of the present invention can establish communication wirelessly, through a data cloud or other means, allowing their operating parameters to be displayed on different devices, accommodating new business opportunities such as the integral energy storage service (monitoring, maintenance, etc.).

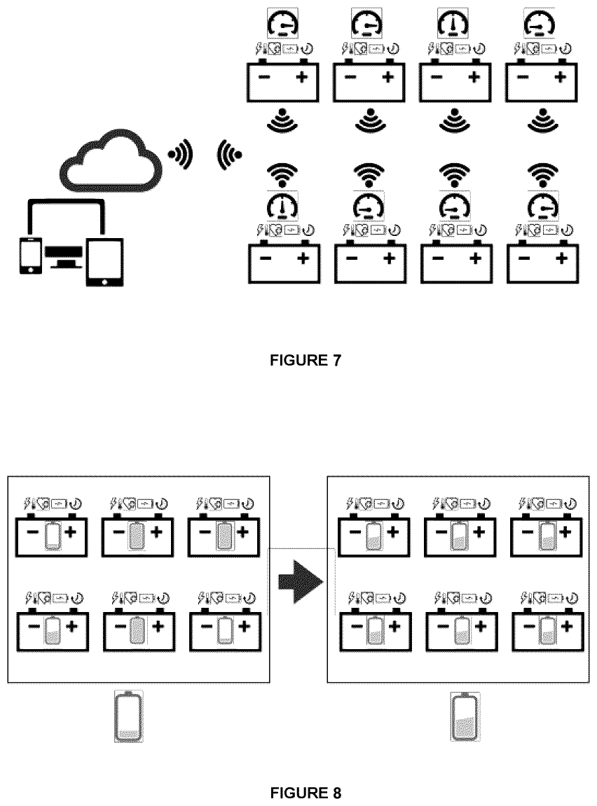

Referring to FIG. 7, this teaches another mode of operation of the control and monitoring system of a rechargeable battery bank, in accordance with a preferred configuration of the invention. The batteries of the present invention have a control system, operated through the protection and balancing device, which allows to regulate the energy entering or leaving them independently, which entails several benefits in terms of efficiency and functionality.

For example, it is possible to cut off the supply remotely, for security reasons, when some parameter is out of what is desired. Energy flow regulation algorithms can also be configured according to what is considered convenient, for example, with the variation of the price of electricity, or during specific times of the day, allowing the batteries to be charged or discharged at a particular time, in a form and at a desired rate, thus having absolute control of the battery bank. It should be noted that this control system can be operated remotely through the management device or autonomously by each of the batteries of the bank through the control, monitoring and communication device of each of them.

FIG. 8 shows a further mode of operation of the control and monitoring system of a rechargeable battery bank, in accordance with a preferred configuration of the invention. Because the batteries of the present invention have the ability to control and regulate the incoming or outgoing energy in each of them individually and because they also have the ability to communicate the charge state of each of them, either between batteries or through the management device, it is possible for the entire battery bank to balance the charge state of all of the batteries thereof. This is achieved by accelerating the process of charging/discharging some, while decelerating that of others. The advantage of having a balanced battery bank at all times is that in this way there are no weak links that condition the operation of the bank, taking advantage of the maximum capacity of all the batteries, not limiting the bank to the remaining energy of the one that is in a more critical state. This allows the bank to be fully charged or discharged and, in addition, to connect batteries having different charge state without having to worry about electrical and/or operating problems that may be generated, since the system of the invention will be responsible for bringing all the batteries of the bank to a same charge state.

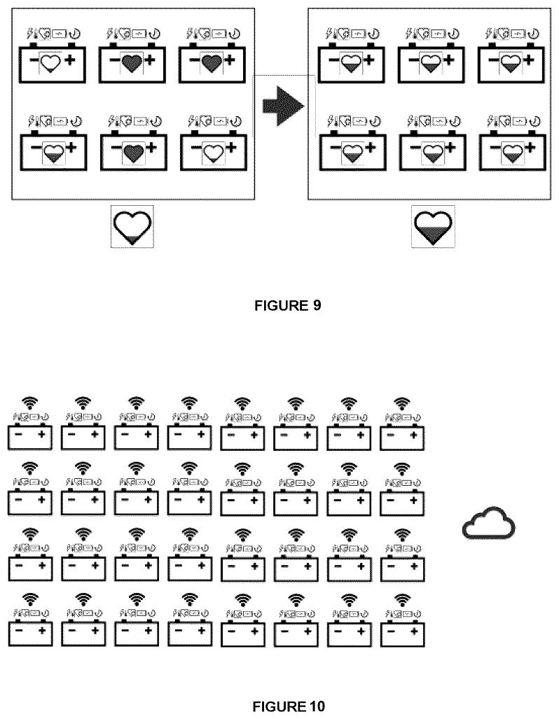

Like FIG. 8, FIG. 9 shows a further mode of operation of the control and monitoring system of a rechargeable battery bank, according to a preferred configuration of the invention. As in the previous case, since it is possible to control or regulate the incoming or outgoing energy for each battery individually and because they also have the ability to communicate the charge state of each one, either between batteries or through the management device, it is possible for the battery bank to balance the state of health of all its batteries. This is achieved by accelerating the charging/discharging process of some, while decelerating in others, in order to increase or decrease the charging/discharging cycles and, consequently, their state of health. The advantage of having a balanced battery bank is that there are no weak links that condition the operation of the bank, thus taking advantage of the maximum lifetime of all batteries, not limited to that with the shortest lifetime. This allows the battery bank to have a longer lifetime and the corresponding replacements to be carried out uniformly, thus being able to schedule a single maintenance or scheduled replacement for the entire bank and not individually or by groups of batteries, decreasing the stopping times of the system. Furthermore, unlike any other type of battery existing today, it is possible to connect the batteries of the present invention, even if they have different degrees of aging, without having problems of efficiency or accelerated aging, due to the fact that the system will be responsible for uniformizing the aging of all the batteries of the bank through the imposition of different charging/discharging rates for each of the batteries.

On the other hand, FIG. 10 shows yet another mode of operation of the control and monitoring system of a rechargeable battery bank, according to a preferred configuration of the invention. Therein it is shown that, since the connectivity is wireless, there is the possibility of scaling the solution unlimitedly, unlike other devices that can solve the problem with cables, which have a clear physical and electronic limitation, due to the number of devices that are able to monitor simultaneously.

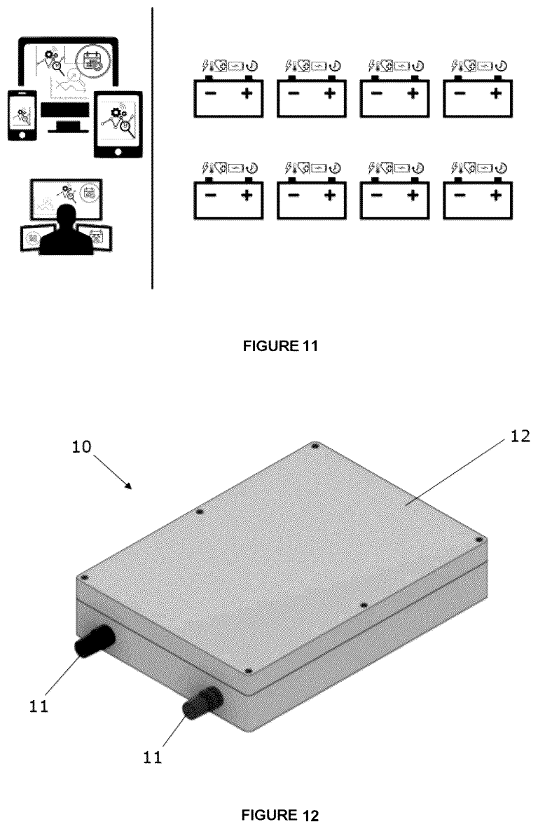

Referring to FIG. 11, this teaches yet another mode of operation of the control and monitoring system of a rechargeable battery bank, in accordance with a preferred configuration of the invention. Due to the possibility of storing the historical data regarding the operating parameters of all the batteries of a battery bank, it is possible to use advanced analysis and prediction tools associated with machine learning algorithms, to be able to predict when maintenance will be required and, thus, to be able to schedule maintenance in advance in the system. This has great benefits when anticipating the customer when maintenance will be carried out, ensuring that their battery bank is always operational. In addition, it allows companies to efficiently manage the resources available for maintenance operations and activities associated with them.

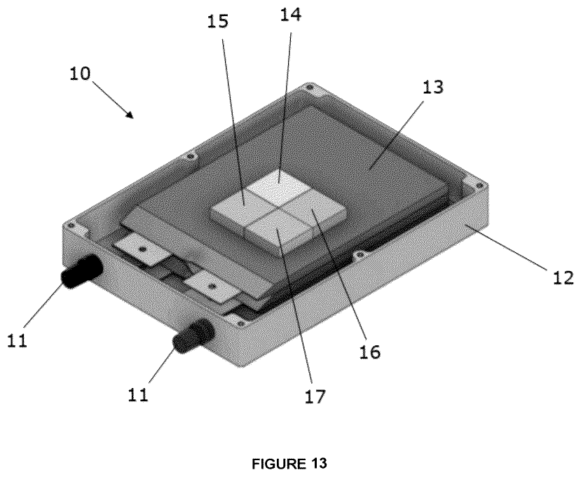

Finally, in FIGS. 12 and 13, different views of the rechargeable battery of the invention are shown, wherein, in FIG. 12, an isometric view of the rechargeable battery (10) is observed, mainly comprising an outer casing (12) and at least two connecting elements (11), such as terminals.

Referring to FIG. 13, the interior of the rechargeable battery (10) and its components are seen, as described throughout this specification. The rechargeable battery (10) according to the embodiment presented in FIG. 13 comprises at least one cell (13), such as a lithium cell or other material allowing energy storage, a protection and balancing device (14), which in turn comprises a voltage sensor, a current sensor and a temperature sensor. In addition, the rechargeable battery (10) comprises a control, monitoring and communication device (15) and, optionally may include an audible alarm (17) and a sensor unit (16), which may comprise at least an impedance sensor, a humidity sensor, a salinity sensor, a vibration sensor, a locating element and a pressure sensor.

From what is shown in FIGS. 12 and 13 the advantages of the rechargeable battery of the invention can be appreciated, which is capable of housing inside it all the devices and sensors necessary to monitor all the variables that the user requires and that are important to maintain control of the battery bank.

1. A method of monitoring and controlling at least one rechargeable battery, comprising the following steps:
measuring the voltage of at least one cell, arranged inside the rechargeable battery, by means of at least one protection and balancing unit, comprising at least one voltage sensor;
measuring the current of the at least one cell, by means of the at least one protection and balancing unit, comprising at least one current sensor;
measuring the temperature of the at least one cell, by means of the at least one protection and balancing unit, comprising at least one temperature sensor;
sending from the at least one protection and balancing unit at least one of the voltage, current and temperature data to the at least one control, monitoring and communication unit;
determining a charge state of the at least one cell, by the at least one control, monitoring and communication unit, using at least one of the voltage, current and temperature data of the at least one cell;
determining a state of health of the at least one cell, by the at least one control, monitoring and communication unit, using at least one of the voltage, current and temperature data of the at least one cell;
determining an estimated charging time of the at least one cell, by the at least one control, monitoring and communication unit, using at least one of the voltage, current and temperature data of the at least one cell;
determining an estimated discharging time of the at least one cell, by the at least one control, monitoring and communication unit, using at least one of the voltage, current and temperature data of the at least one cell;
determining an estimated time of replacement of the at least one cell, by the at least one control, monitoring and communication unit, using at least one of the voltage, current and temperature data of the at least one cell;
storing in the at least one control, monitoring and communication unit at least one of the data on voltage, current, temperature, charge state, state of health, estimated charging time, estimated discharging time and estimated time of replacement;
sending from the at least one control, monitoring and communication unit at least one of the data on voltage, current, temperature, charge state, state of health, estimated charging time, estimated discharging time and estimated time of replacement, to the at least one management device;
displaying at least one of the data on voltage, current, temperature, charge state, state of health, estimated charging time, estimated discharging time and estimated time of replacement for the at least one cell, by at least one display device;
comparing, by the at least one control, monitoring and communication unit and/or by the at least one management device, at least one of the obtained data on voltage, current, temperature, charge state, state of health, estimated charging time, estimated discharging time and estimated time of replacement with at least one range of preset values for each of them in the at least one control, monitoring and communication unit and in the at least one management device;
assessing whether it corresponds to initiate at least one preventive action and/or a corrective action in the at least one cell, by means of the at least one control, monitoring and communication unit and/or by means of the at least one management device;
when appropriate to initiate at least one preventive and/or corrective action, carrying out said preventive and/or corrective action in the at least one cell by the at least one control, monitoring and communication unit and/or by the at least one management device; and
using at least one of the data on voltage, current, temperature, charge state, state of health, estimated charging time, estimated discharging time and estimated time of replacement for the at least one cell, in evaluating future preventive and/or corrective actions in said at least one cell by the at least one control, monitoring and communication unit and/or by the at least one management device;
wherein initiating at least one preventive action and/or a corrective action at least comprises:
regulating the flow of energy entering or leaving the at least one cell, by means of the at least one energy regulating element, comprising the at least one protection and balancing unit.

2. The method according to claim 1, further comprising issuing an audible alert, by at least one audible alarm, when at least one of the data on voltage, current, temperature, estimated charging time, and estimated discharging time are outside of the at least one preset range for each of them.

3. The method according to claim 1, further comprising sending an alert from the at least one control, monitoring and communication unit and/or from the at least one management device, to the at least one display device, when at least one of the data on voltage, current, temperature, estimated charging time and estimated discharging time are outside of the at least one preset range for each of them.

4. The method according to claim 1, further comprising, when at least one of the current, voltage and temperature data for the at least one cell is outside the at least one preset range for each of them, cutting the connection between the at least one rechargeable battery and the outside, by at least one disconnecting element, and placing the at least one at least one rechargeable battery in the alert state, by the at least one control, monitoring and communication unit and/or by the at least one management device.

5. The method according to claim 1, wherein the regulating the flow of energy entering or leaving the at least one cell by the at least one energy regulating element is performed between an open and closed state.

6. The method according to claim 1, wherein regulating the flow of energy entering or leaving the at least one cell, by the at least one energy regulating element, is performed among 0% flow of energy entering or leaving 100% energy entering or leaving.

7. The method according to claim 1, wherein the method further comprises, in case the charge state data for the at least one cell is below the at least one preset range, during a charging process of the at least one rechargeable battery:
increasing the flow of energy to the at least one cell in which the charge state data is below the at least one preset range, by its at least one energy regulating element

8. The method according to claim 1, further comprising, in case the charge state data for the at least one cell is below the at least one preset range, during a charging process of the at least one rechargeable battery:
establishing communication between the at least one control, monitoring and communication unit and at least one other control, monitoring and communication unit associated with another rechargeable battery; or
establishing communication between the at least one control, monitoring and communication unit and the at least one management device, such that it establishes communication with at least one other control, monitoring and communication unit associated with another rechargeable battery; or
establishing a communication, by the management device, between the at least one control, monitoring and communication unit with at least one other control, monitoring and communication unit associated with another rechargeable battery;
decreasing the energy flow to the at least one cell in the other rechargeable battery, by its at least one energy regulating element; and
increasing the flow of energy to the at least one cell in which the charge state data is below the at least one preset range, by its at least one energy regulating element.

9. The method according to claim 8, wherein decreasing the flow of energy to the at least one cell in the other rechargeable battery, by its at least one energy regulating element; and increasing the flow of energy to the at least one cell in which the charge state data is below the at least one preset range, by its at least one energy regulating element, are performed until the charge state data for the at least one cell in which the charge state data is below the at least one preset range is again within the at least one preset range.

10. The method according to claim 1, further comprising, when the charge state data for the at least one cell is within or above the at least one preset range, during a charging process of the at least one rechargeable battery:
establishing communication between the at least one control, monitoring and communication unit and at least one other control, monitoring and communication unit associated with another rechargeable battery; or
establishing communication between the at least one control, monitoring and communication unit and the at least one management device, such that it establishes communication with at least one other control, monitoring and communication unit associated with another rechargeable battery; or
establishing a communication, by the management device, between the at least one control, monitoring and communication unit with at least one other control, monitoring and communication unit associated with another rechargeable battery;
decreasing the flow of energy to the at least one cell in which the charge state data is within or above the at least one preset range, by its at least one energy regulating element; and
increasing the flow of energy to the at least one cell in the other rechargeable battery, by its at least one energy regulating element.

11. The method according to claim 10, wherein decreasing the flow of energy to the at least one cell in which the charge state data is within or above the at least one preset range, by its at least one energy regulating element; and increasing the flow of energy to the at least one cell in the other rechargeable battery, by its at least one energy regulating element, are performed until the charge state data for the at least one cell in which the charge state data is within or above the at least one preset range is again within the at least one preset range.

12. The method according to claim 1, wherein the method further comprises, in case the charge state data for the at least one cell is below the at least one preset range, during a discharging process of the at least one rechargeable battery:
decreasing the flow of energy being discharged from the at least one cell in which the charge state data is below the at least one preset range, by its at least one energy regulating element.

13. The method according to claim 1, further comprising, in case the charge state data for the at least one cell is below the at least one preset range, during a discharging process of the at least one rechargeable battery:
establishing communication between the at least one control, monitoring and communication unit and at least one other control, monitoring and communication unit associated with another rechargeable battery; or
establishing communication between the at least one control, monitoring and communication unit and the at least one management device, such that it establishes communication with at least one other control, monitoring and communication unit associated with another rechargeable battery; or
establishing a communication, by the management device, between the at least one control, monitoring and communication unit with at least one other control, monitoring and communication unit associated with another rechargeable battery;
increasing the flow of energy being discharged from the at least one cell in the other rechargeable battery, by its at least one energy regulating element; and
decreasing the flow of energy being discharged from the at least one cell in which the charge state data is below the at least one preset range, by its at least one energy regulating element.

14. The method according to claim 13, wherein increasing the flow of energy being discharged from the at least one cell into the other rechargeable battery, by its at least one energy regulating element; and decreasing the flow of energy being discharged from the at least one cell in which the charge state data is below the at least one preset range, by its at least one energy regulating element, are performed until the charge state data for the at least one cell in which the charge state data is below the at least one preset range is again within the at least one preset range.

15. The method according to claim 1, further comprising, when the charge state data for the at least one cell is within or above the at least one preset range, during a discharging process of the at least one rechargeable battery:
establishing communication between the at least one control, monitoring and communication unit and at least one other control, monitoring and communication unit associated with another rechargeable battery; or
establishing communication between the at least one control, monitoring and communication unit and the at least one management device, such that it establishes communication with at least one other control, monitoring and communication unit associated with another rechargeable battery;
establishing a communication, by the management device, between the at least one control, monitoring and communication unit with at least one other control, monitoring and communication unit associated with another rechargeable battery;
increasing the flow of energy being discharged from the at least one cell in which the charge state data is within or above the at least one preset range, by its at least one energy regulating element; and
decreasing the flow of energy being discharged from the at least one cell in the other rechargeable battery, by its at least one energy regulating element.

16. The method according to claim 15, wherein increasing the flow of energy being discharged from the at least one cell in which the charge state data is within or above the at least one preset range, by its at least one energy regulating element; and decreasing the flow of energy being discharged from the at least one cell into the other rechargeable battery, by its at least one energy regulating element, are performed until the charge state data for the at least one cell in which the charge state data is below the at least one preset range is again within the at least one preset range.

17. The method according to claim 1, further comprising, in case the charge state data for the at least one cell is at its maximum value, stopping the flow of energy to the at least one cell, by the at least one energy regulating element.

18. The method according to claim 1, further comprising, in case the charge state data for the at least one cell is at or below a minimum value, stopping the flow of energy discharging from the at least one cell, by the at least one energy regulating element.

19. The method according to claim 2, further comprising, when the charge state data for the at least one cell is at or below the minimum value, emitting an audible alert by the at least one audible alarm.

20. The method according to claim 1, further comprising, when the charge state data for the at least one cell is at or below the minimum value, sending an alert from the at least one control, monitoring and communication unit and/or from the at least one management device, towards the at least one display device.

21. The method according to claim 1, further comprising, in case the data of state of health for the at least one cell is below the at least one preset range, decreasing a charge/discharge cycles in the at least one cell, by the at least one control, monitoring and communication unit and/or by the at least one management device, until the data of state of health for the at least one cell is within the at least one preset range.

22. The method according to claim 1, further comprising, in case the data of state of health for the at least one cell is above the at least one preset range, increasing the charge/discharge cycles in the at least one cell, by the at least one control, monitoring and communication unit and/or by the at least one management device, until the data of state of health for the at least one cell is within the at least one preset range.

23. The method according to claim 2, further comprising, when the health state data for the at least one cell is at or below a minimum value, emitting an audible alert by the at least one audible alarm.

24. The method according to claim 1, further comprising, in case the data of state of health for the at least one cell is at or below its minimum value, sending an alert from the at least one control, monitoring and communication unit and/or from the at least one management device, towards the at least one display device indicating the need for replacement for the at least one cell.

25. The method according to claim 1, further comprising, in case the data on estimated time of replacement for the at least one cell is below the at least one preset range, decreasing a charge/discharge cycles in the at least one cell until the data on estimated time of replacement for the at least one cell is within the at least one preset range, by the at least one control, monitoring and communication unit and/or by the at least one management device.

26. The method according to claim 1, further comprising, in case the data on estimated time of replacement for the at least one cell is above the at least one preset range, increasing charge/discharge cycles in the at least one cell until the data on estimated time of replacement for the at least one cell is within the at least one preset range, by the at least one control, monitoring and communication unit and/or by the at least one management device.

27. The method according to claim 2, further comprising, when the data on estimated time of replacement for the at least one cell is at or below a minimum value, emitting an audible alert by the at least one audible alarm.

28. The method according to claim 1, further comprising, in case the data on estimated time of replacement for the at least one cell is at or below its minimum value, sending an alert from the at least one control, monitoring and communication unit and/or from the at least one management device, towards the at least one display device indicating the need for replacement for the at least one cell.

29. The method according to claim 1, further comprising measuring the impedance of the at least one cell, by the at least one protection and balancing unit, comprising at least one impedance sensor.

30. The method according to claim 1, further comprising measuring the humidity outside the at least one cell, by means of the at least one protection and balancing unit, comprising at least one humidity sensor.

31. The method according to claim 1, further comprising measuring the salinity on the outside of the at least one cell, by means of the at least one protection and balancing unit, comprising at least one salinity sensor.

32. The method according to claim 31, wherein at least one of the steps of determining a charge state, determining a state of health, determining an estimated charging time, determining an estimated discharging time, and determining an estimated time of replacement, for the at least one cell, by the at least one control, monitoring and communication unit, further comprises using at least one of the impedance, humidity and salinity data of the at least one cell.

33. The method according to claim 1, further comprising measuring the vibrations in the rechargeable battery, by means of a vibration sensor.

34. The method according to claim 1, further comprising monitoring the position of the rechargeable battery, by means of a locating element.

35. The method according to claim 1, further comprising measuring the pressure inside the rechargeable battery, by means of a pressure sensor.

36. The method according to claim 1, further comprising monitoring the opening and closing of an outer casing of the rechargeable battery, by means of an opening sensor.

37. The method according to claim 27, further comprising comparing at least one of the obtained data on vibrations, position, pressure and opening and closing of the outer casing with at least one range of preset values for each of them in the at least one control and monitoring unit and in the at least one management device.

38. The method according to claim 37, further comprising, in the event of one or more of the data on vibrations, position, pressure and opening and closing of the outer casing are outside the at least one range of preset values for each of them, emitting an audible alert by the at least one audible alarm.

39. The method according to claim 37, further comprising, in the event of one or more of the data on vibrations, position, pressure and opening and closing of the outer casing are outside the at least one range of preset values for each of them, sending an alert from the at least one control, monitoring and communication unit towards the at least one display device.

40. A rechargeable battery comprising:
at least one outer casing;
at least two connecting elements;
at least one cell;
at least one protection and balancing unit, comprising:
at least one voltage sensor;
at least one current sensor;
at least one temperature sensor;
at least one energy regulating element; and
at least one control, monitoring and communication unit.

41. The rechargeable battery according to claim 40, further comprising at least one display device.

42. The rechargeable battery according to claim 40, wherein the at least one protection and balancing unit further comprises at least one disconnecting member.

43. The rechargeable battery according to claim 40, further comprising at least one audible alarm.

44. The rechargeable battery according to claim 40, further comprising at least one impedance sensor.

45. The rechargeable battery according to claim 40, further comprising at least one humidity sensor.

46. The rechargeable battery according to claim 40, further comprising at least one salinity sensor.

47. The rechargeable battery according to claim 40, wherein the at least one protection and balancing unit and the at least one control, monitoring and communication unit perform data communications via cables.

48. The rechargeable battery according to claim 40, wherein the at least one protection and balancing unit and the at least one control, monitoring and communication unit perform data communications via 3G, 4G, 5G, Bluetooth, infrared, radiofrequency, NFC, Wifi, LoRa, LoRaWan wireless networks or any other network that allows wireless communication.

49. The rechargeable battery according to claim 40, further comprising at least one vibration sensor.

50. The rechargeable battery according to claim 40, further comprising at least one locating element.

51. The rechargeable battery according to claim 40, further comprising at least one pressure sensor.

52. The rechargeable battery according to claim 40, further comprising at least one opening sensor.

53. The rechargeable battery according to claim 44, wherein at least one of the impedance sensor, the humidity sensor, the salinity sensor, the vibration sensor, the locating element and the pressure sensor is comprised by the at least one protection and balancing unit.

54. The rechargeable battery according to claim 44, wherein at least one of the impedance sensor, the humidity sensor, the salinity sensor, the vibration sensor, the locating element and the pressure sensor is comprised by at least one sensor unit.

55. A rechargeable power supply system, comprising:
at least one rechargeable battery, according to claim 40;
at least one management device; and
at least one display device.
